(19) United States
(12) Patent Application Publication
(10) Pub. No.: US 2007/0217166 A1
(43) Pub. Date: Sep. 20, 2007

(54) Micro secure digital memory card

(76) Inventor: Chin-Chun Liu, Pingjhen City (TW)

Correspondence Address: Dykema Gossett, PLLC, Suite 300 West, 1300 I Street, N.W., Washington, DC, 20005-3306, US

(21) Appl. No.: 11/378,316

(22) Filed: Mar. 20, 2006

(51) Int. Cl. H05K 1/14

(52) U.S. Cl. 361/737

(57) ABSTRACT

The present invention provides an improved Micro SD memory card, wherein the Micro SD memory card comprises a memory unit, a frame and a cover. The memory card comprises a package of a complete integrated circuit and essential electrical devices, wherein one side of the memory unit further comprises a plurality of contact pieces, and a protruding portion is formed on a circumferential side of the memory unit. The frame has a locating area for positioning the memory unit, wherein a trench is formed on a circumferential edge of one side of the frame. A channel part is formed on another side of the frame and corresponds to the protruding portion of the memory unit. The cover locating onto one side of the frame, wherein an inserting portion is formed and is integrated into the trench of the frame. The frame's structure can be integrated either on the complete integrated package or the unpacking package.

### BACKGROUND OF THE INVENTION

1. Field of Invention

The present invention relates to an improved Micro Secure Digital Card (Micro SD) card. More particularly, the present invention relates to a memory unit that is suitable to be utilized on a complete assembled package or on an unpacking package, wherein the structure of the memory card package is simplified and the memory card package can be assembled rapidly in order to increased its productivity. Furthermore, the manufacturing cost is decreased and the exchangeable function of the memory cards' utilization is achieved.

2. Description of the Related Art

With the increasing demands of electrical integrated circuits in various areas, the technology of electrical integrated circuit has been developed rapidly over last few years. While the utility and usefulness of the electrical integrated circuits increase, various types of electrical integrated circuits have been developed to provide higher performance. The current structural design of the electrical integrated circuit is moved towards to a much lighter structure, which is portable easily and small in size, such as those used in the digital camera, the electronic dictionary and the digital video machine.

The Micro secure digital card( Micro SD) memory card is currently the latest memory card design, its size is much smaller than the Smart Media Card or the Compact Flash Card. Furthermore, it is more compact and its weight is lighter. The Micro SD memory card comprises a high comparability, a high storage capacity, and its fabrication is less than other memory cards. Moreover, the Micro SD memory card has a high performance to transmit data much faster and provides excellent security. The Micro SD memory card is suitable to be used on cellular phones, the PDA, computers or other media storing devices.

The conventional Micro SD memory card 4 is shown on FIGS. 1 and 2, wherein the fabrication process is actually a packaging process. The contact pieces 41 is packaged to form a rectangular shaped structure as shown on FIG. 2. Once the package is completed, the package is cut by a machine or an electrical cutter in order to produce a desirable shape. The package is then integrated to form the conventional Micro SD memory card 4. Therefore, this kind of packaging process is complex, and it induces a high manufacturing cost and is time consuming, as a result, the productivity of the Micro SD memory card 4 is low. The prior art, Micro SD memory card 4, once the circumferential edges 42 is cut by a machine, its shape would form with sharp edges which are not suitable for utilizing on a reader device or a device that is required exchangeable units. Thus, the conventional Micro SD memory card 4 does not have a practical structural design and its application is limited to certain areas.

### SUMMARY OF THE INVENTION

It is an object of the present invention to provide an improved structure of a Micro SD memory card that is capable to overcome those disadvantages induced by the conventional Micro SD memory card. The present invention provides an improved Micro SD memory card that can utilize a frame's structure to integrate either on a complete integrated package and an unpacking package. The present invention provides an improved Micro SD memory card that not only has a simplified integrating structure, it also can be rapidly assembled so that the productivity can be increased. As a matter of fact, the fabrication cost of the improved Micro SD memory card is decreased, and the utilization of the improved Micro SD memory card also comprises exchangeable function.

The present invention provides an improved Micro SD memory card, wherein the Micro SD memory card comprises a memory unit, a frame and a cover. The memory card comprises a package of a complete integrated circuit and essential electrical devices, wherein one side of the memory unit further comprises a plurality of contact pieces, and a protruding portion that is formed on a circumferential side of the memory unit. The frame has a locating area for positioning the memory unit, wherein a trench is formed on a circumferential edge of one side of the frame. A channel part is formed on another side of the frame and corresponds to the protruding portion of the memory unit. The cover locating onto one side of the frame, wherein an inserting portion is formed and is integrated into the trench of the frame.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIG. 1 is a 3-D view of a conventional Micro SD memory card;

FIG. 2 shows another 3-D view of the conventional Micro SD memory card;

FIG. 3 illustrates an assembly view of an improved Micro SD memory card in accordance with a preferred example of the present invention;

FIG. 4 is a 3-D view of an assembled improved Micro SD memory card in accordance with the preferred example of the present invention;

FIG. 5A illustrates a cross-sectional view along a cutting line A-A of the assembled improved Micro SD memory card of FIG. 4 in accordance with the preferred example of the present invention;

FIG. 5B shows a magnified view of portion a of FIG. 5A;

FIG. 5C is a magnified view of portion b of FIG. 5A;

FIG. 6A illustrates a cross-sectional view along a cutting line B-B of the assembled improved Micro SD memory card of FIG. 4 in accordance with the preferred example of the present invention;

FIG. 6B shows a magnified view of portion c of FIG. 6A;

FIG. 6C illustrates a magnified view of portion d of FIG. 6A;

FIG. 7 shows a 3-D assembly view of an improved Micro SD memory card in accordance with another preferred example of the present invention;

FIG. 8 is a cross-sectional view of the improved Micro SD memory card in accordance with the preferred example of FIG. 7.

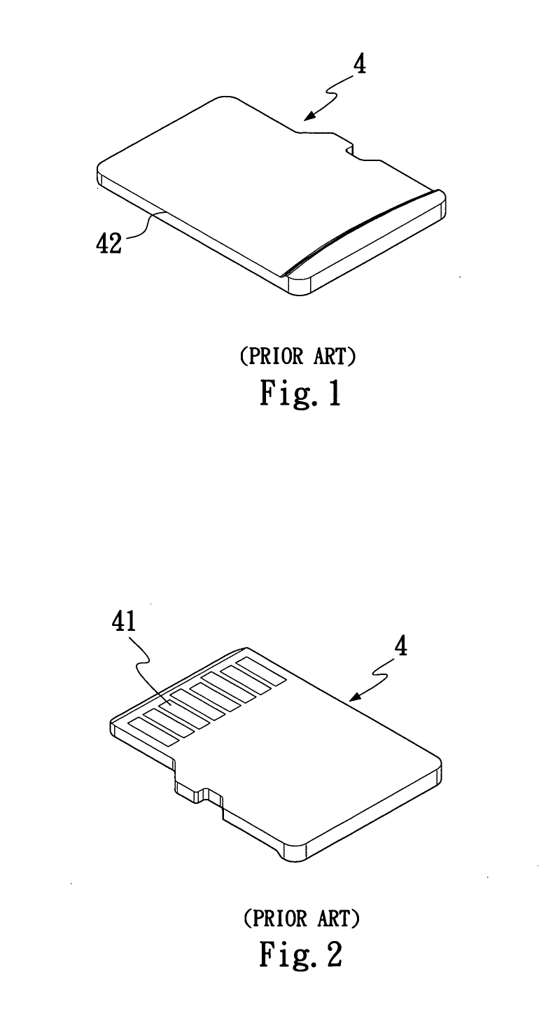

### DESCRIPTION OF THE PREFERRED EMBODIMENTS

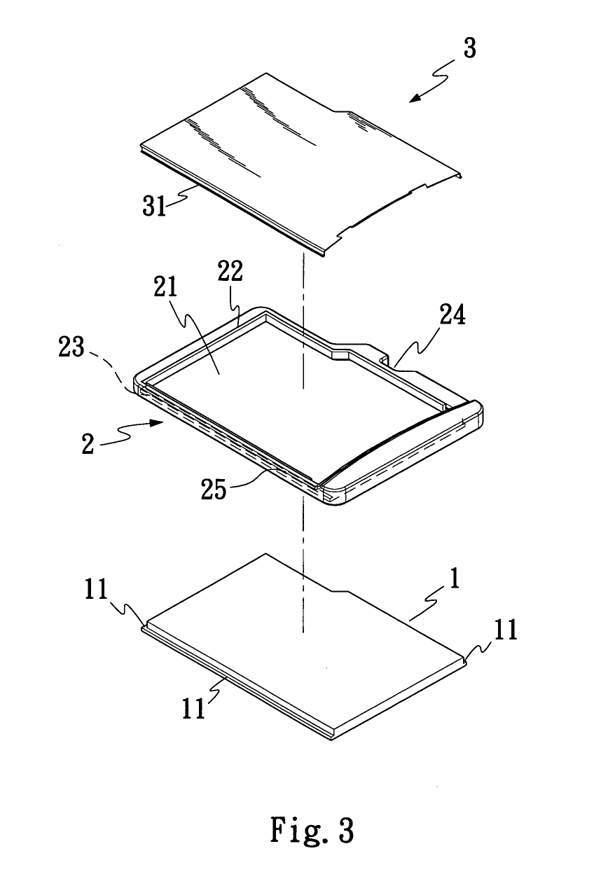

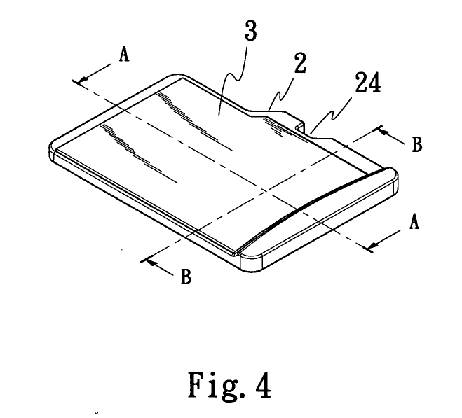

Refer to FIGS. 3 and 4, an assembly view of an improved Micro SD (Micro Secure Digital) memory card in accordance with a preferred example of the present invention. The improved Micro SD memory card of the present invention comprises a memory unit 1, a frame 2 and a cover 3, wherein the structural design of the memory card 1 can allow the memory card to be utilized on a complete assembled package or on an unpacking package. In fact, the present invention provides an improved memory card that comprises a simplified packaging structure, and the memory card package can be assembled rapidly. Furthermore, the productivity of the memory cards can be increased, the manufacturing cost is reduced and the exchangeable of utilizing memory cards can also be achieved.

The above-mentioned memory unit 1 comprises a package of a complete integrated circuit and essential electrical devices. The memory card comprises a plurality of contact flat pieces on one surface area of the memory unit 1 (not shown in the drawings). The memory unit 1 further comprises one protruding portion 11 located on at least three circumferential sides of the memory unit 1.

The frame 2 is made of plastic materials and comprises a locating area 21 therein. The frame 2 further comprises a trench 22 positioning on at least three circumferential edges of one side of the frame 2. One of sides of the frame 2 comprises a channel part 23 that corresponds to the protruding portion 11 of the memory unit 1, and an opening 24 is formed on an external part of the frame 2. An arc surface 25 is formed on an external circumferential edge of another external part of the frame 2.

The cover 3 is made of metal materials and is positioned onto a top surface of the frame 2. Circumferential edges of the cover 3 comprise inserting portions 31 integrated into the trench 22 of the frame 2. Thus, an improved structure of a Micro SD memory card is provided.

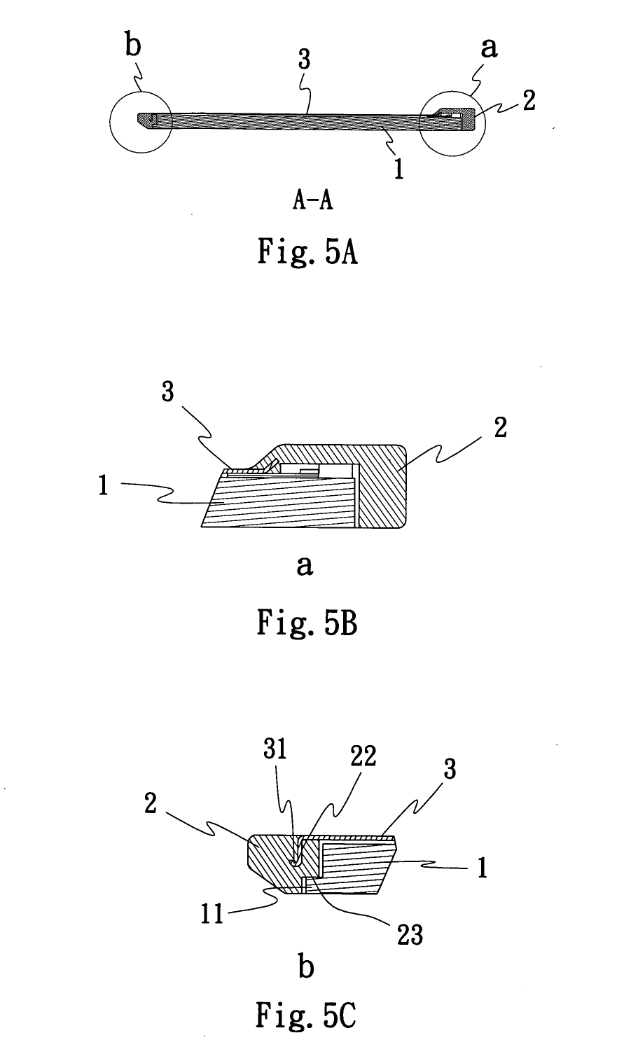

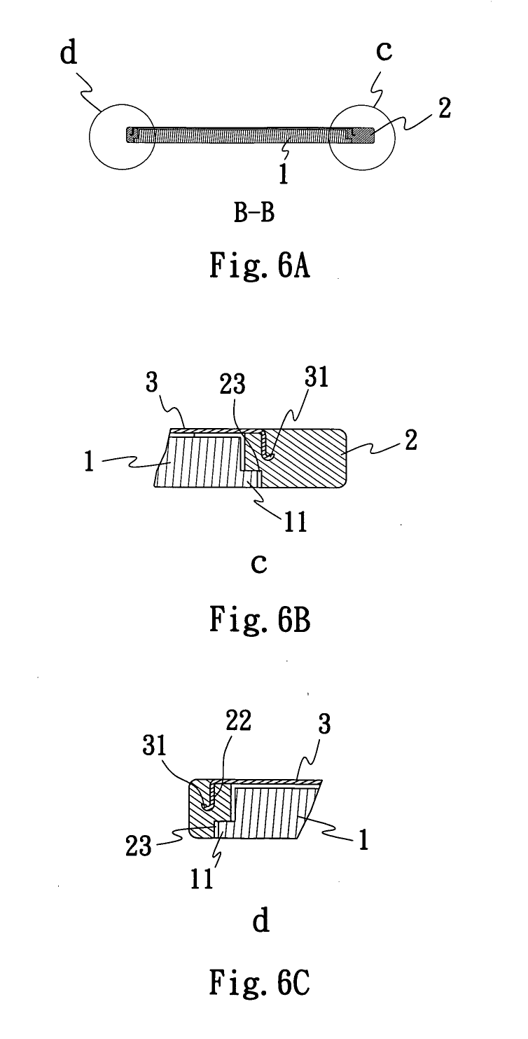

Refer to FIGS. 5A-6C, wherein FIG. 5A illustrates a cross-sectional view along a cutting line A-A of the assembled improved Micro SD memory card of FIG. 4 in accordance with the preferred example of the present invention. FIG. 5B shows a magnified view of portion a of FIG. 5A, and FIG. 5C is a magnified view of portion b of FIG. 5A. On the other hand, FIG. 6A illustrates a cross-sectional view along a cutting line B-B of the assembled improved Micro SD memory card of FIG. 4 in accordance with the preferred example of the present invention. FIG. 6B shows a magnified view of portion c of FIG. 6A, and FIG. 6C illustrates a magnified view of portion d of FIG. 6A.

When the components of the Micro SD memory card of the present invention are integrated together, the frame is assembled onto the cover 3 with an inserter molding method to cover an outer section of the cover 3 so that the arc surface 25 of the frame 2 located on the external circumferential edge of the assembled structure is formed. After the frame 2 being projected to confine its shape, the trenches 22 of the frame 2 is then integrated firmly to the inserting portions 31 of the cover 3. The memory unit 1 utilizes a circumference of a circuit board 12 to correspond with the channel part 23 of the frame 2 in such that a heating method or a supersonic method is used to integrate the assembly memory card structure. The memory unit 1 is then located inside the locating area 21 of the frame 2 so that the memory card can utilize the structure of the frame to integrate with the memory unit 1. Thus, a simplified integrating structure with a rapid integrating process can be achieved in order to improve its productivity and, simultaneously reduce its fabrication cost. The guidance of the arc surface 25 of the frame 2 is utilized to assist the exchangeable function of the utilization of the memory card.

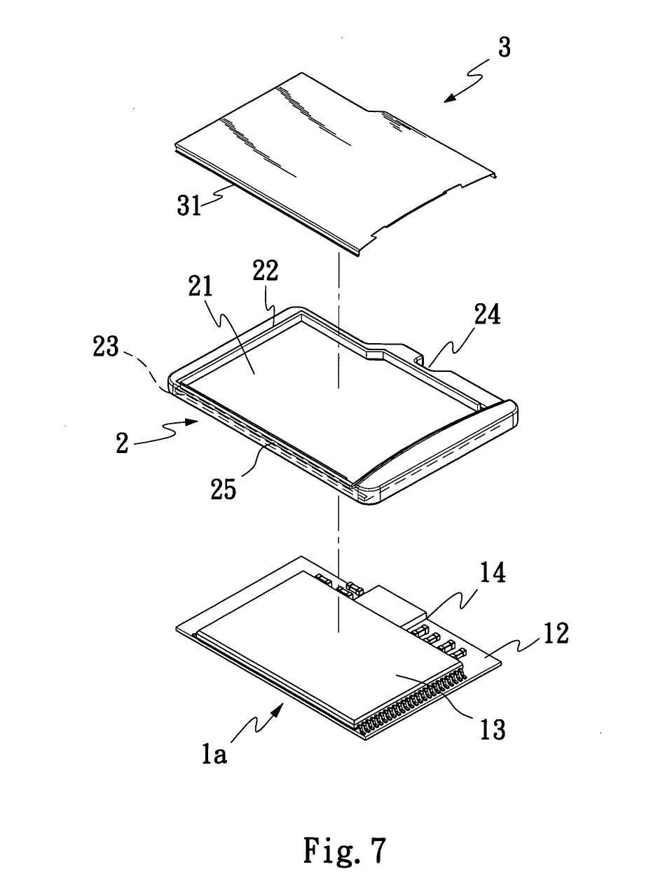

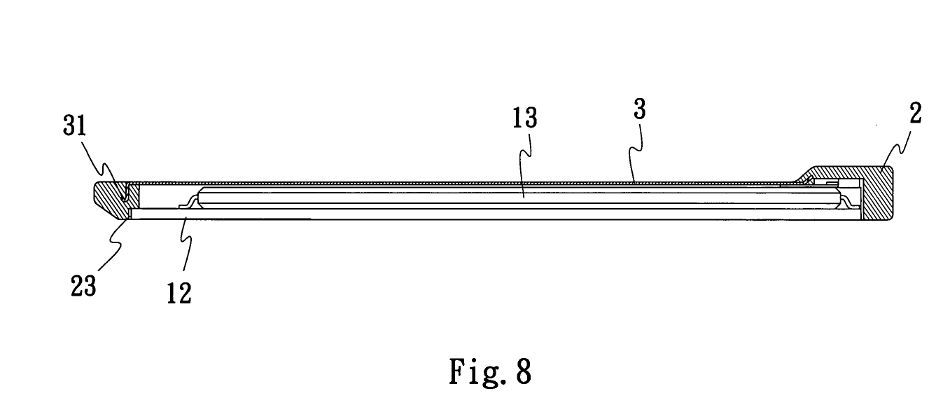

FIGS. 7 and 8, shows a 3-D assembly view and a cross-sectional view of an improved Micro SD memory card in accordance with another preferred example of the present invention. The present invention provides an improved Micro SD memory card comprising an integrated circuit 13 of an electrical circuit board 12 and essential electrical devices 14. The memory unit 1a further comprises one protruding portion 11 located on at least three circumferential sides of the memory unit 1a.

When the components of the Micro SD memory card of the present invention are integrated together, the frame is assembled onto the cover 3 with an inserter molding method to cover an outer section of the cover 3 so that the arc surface 25 of the frame 2 located on the external circumferential edge of the assembled structure is formed. After the frame 2 being projected to confine its shape, the trenches 22 of the frame 2 is then integrated firmly with the inserting portions 31 of the cover 3. The memory unit 1a utilizes a circumference of a circuit board 12 to correspond with the channel part 23 of the frame 2, wherein a heating method or a supersonic method is used to integrate the assembly memory card structure. The memory unit 1a is located inside the locating area 21 of the frame 2 so that the memory card can utilize the structure of the frame to integrate with the memory unit 1a. Thus, a simplified integrating structure with a rapid integrating process can be achieved in order to improve its productivity and, simultaneously reduce its fabrication cost. The guidance of the arc surface 25 of the frame 2 is utilized to assist the exchangeable function of the utilization of the memory card.

The present invention provides an improved structure of the Micro SD memory card that is capable to overcome the disadvantages induced by the conventional Micro SD memory card. The present invention provides an improved Micro SD memory card that can utilize its frame's structure to integrate either on the complete assembled package or the unpacking package. The present invention provides an improved Micro SD memory card that not only has a simplified integrating structure, its components can be rapidly assembled in such that the productivity of the Micro SD memory card can be increased and, the fabrication cost can be decreased. The utilization of the improved Micro SD memory card also comprises an exchangeable function.

With the invention has been described by way of example and in terms of a preferred example embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. An improved Micro SD memory card, comprising:
a memory unit, wherein the memory card comprises a package of a complete integrated circuit and essential electrical devices, one side of the memory unit further comprises a plurality of contact pieces, and a protruding portion is formed on a circumferential side of the memory unit;
a frame, having a locating area for positioning the memory unit, wherein a trench is formed on a circumferential edge of one side of the frame, a channel part is formed on another side of the frame and corresponds to the protruding portion of the memory unit; and
a cover, locating onto one side of the frame, wherein an inserting portion is formed and is integrated into the trench of the frame.

2. The improved Micro SD memory card of claim 1, wherein protruding portions are formed on at least three circumferential sides of the memory unit.

3. The improved Micro SD memory card of claim 1, wherein the frame is made from one of plastic materials.

4. The improved Micro SD memory card of claim 1, wherein an arc surface is formed on a circumferential side of an external part of the frame.

5. The improved Micro SD memory card of claim 1, wherein an opening is formed on another external part of the frame.

6. The improved Micro SD memory card of claim 1, wherein trenches are formed on at least three circumferential edges of one side of the frame.

7. The improved Micro SD memory card of claim 1, wherein the cover is made of one of metal materials.

8. An improved Micro SD memory card, comprising:
a memory unit, wherein the memory unit comprises least an integrated circuit locating on an electrical circuit board and essential electrical devices, wherein one side of the memory unit further comprises a plurality of contact pieces;
a frame, having a locating area for positioning the memory unit, wherein a trench is formed on a circumferential edge of one side of the frame, a channel part is formed on another side of the frame and corresponds to a circumferential edge of the electrical circuit; and
a cover, locating onto one side of the frame, wherein an inserting portion is formed and is integrated into the trench of the frame.

9. The improved Micro SD memory card of claim 8, wherein the frame is made from one of plastic materials.

10. The improved Micro SD memory card of claim 8, wherein an arc surface is formed on an external circumferential side of an external part of the frame.

11. The improved Micro SD memory card of claim 8, wherein an opening is formed on another external part of the frame.

12. The improved Micro SD memory card of claim 8, wherein trenches are formed on at least three circumferential edges of one side of the frame.

13. The improved Micro SD memory card of claim 8, wherein the cover is made of one of metal materials.
